(19) United States
(12) Patent Application Publication
(10) Pub. No.: US 2024/0379489 A1
(43) Pub. Date: Nov. 14, 2024

(54) SEMICONDUCTOR PACKAGE DEVICE AND METHOD OF MANUFACTURING SEMICONDUCTOR PACKAGE DEVICE

(71) Applicant: SHUNSIN TECHNOLOGY (ZHONG SHAN) LIMITED, Zhongshan (CN)

(72) Inventor: SHUN-HSING LIAO, Zhongshan City (CN)

(21) Appl. No.: 18/227,311

(22) Filed: Jul. 28, 2023

(30) Foreign Application Priority Data
May 8, 2023 (CN) 202310512617.0

(51) Int. Cl. H01L 23/367; H01L 21/56; H01L 23/00; H01L 23/31; H01L 25/16

(52) U.S. Cl. CPC H01L 23/3675; H01L 21/568; H01L 23/3185; H01L 24/13; H01L 24/20; H01L 24/73; H01L 25/165; H01L 2224/13023; H01L 2224/211; H01L 2224/214; H01L 2224/73101; H01L 2924/1011; H01L 2924/10158

(57) ABSTRACT

A semiconductor package device and a method of manufacturing thereof are provided. The semiconductor package device includes a circuit layer including a conductive circuit, and conductive pads connected to the conductive circuit; a chip disposed on the circuit layer, and connected to the conductive circuit, wherein the chip has a side surface, an upper surface, and heat-dissipation grooves formed on the upper surface; and an encapsulation layer covering on the circuit layer, and covering the side surface of the chip. The heat-dissipation grooves are exposed from the encapsulation layer.

### FIELD

The subject matter herein generally relates to a semiconductor package device having heat-dissipation grooves, and a method of manufacturing thereof.

### BACKGROUND

Due to the progress of the chip, the performance of the chip has been continuously increased, but it has also caused the chip to generate higher heat, and it is necessary to install a heat dissipation structure to meet the heat dissipation requirements. However, on the other hand, electronic devices continue to be miniaturized, which limits the size of the semiconductor package device and its heat dissipation structure.

Therefore, it is necessary to provide an improved solution for the semiconductor package device, which can have good heat dissipation performance under the limitation of the size of the semiconductor package device.

### BRIEF DESCRIPTION OF THE DRAWINGS

Many aspects of the present disclosure are better understood with reference to the following drawings. The components in the drawings are not necessarily drawn to scale, the emphasis instead being placed upon clearly illustrating the principles of the present disclosure. It will be appreciated that for simplicity and clarity of illustration, where appropriate, reference numerals have been repeated among the different figures to indicate corresponding or analogous elements.

FIG. 1 is a schematic diagram of a semiconductor package device 1 in accordance with an embodiment of the present application.

FIG. 2 to FIG. 5 are schematic diagrams of the semiconductor package device 1 in the manufacturing process according to an embodiment of the present application.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The disclosure is illustrated by way of embodiments and not by way of limitation in the figures of the accompanying drawings, in which like references indicate similar elements. It should be noted that references to “an” or “one” embodiment in this disclosure are not necessarily to the same embodiment, and such references mean “at least one.”

The term “connect” is defined as directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series, and the like.

In the present disclosure, the heat dissipation performance of a semiconductor package device is increased by forming grooves on a chip of the semiconductor package device, so as to meet the heat dissipation requirements of the semiconductor package device.

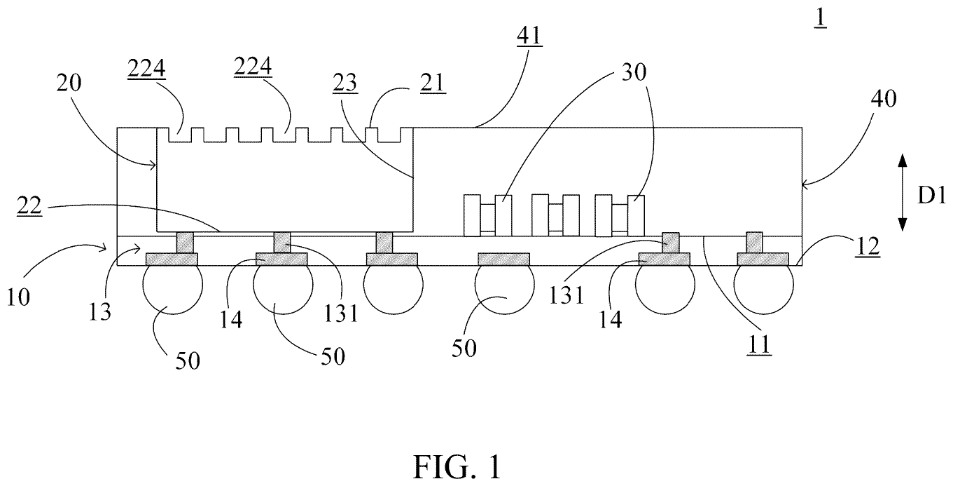

FIG. 1 is a schematic diagram of a semiconductor package device 1 in accordance with an embodiment of the present disclosure. As shown in FIG. 1, the semiconductor package device 1 includes a circuit layer 10, a chip 20, passive components 30, an encapsulation layer 40, and conductive terminals 50. The circuit layer 10 extends perpendicular to a stacking direction D1. The upper surface 11 and the lower surface 12 of the circuit layer 10 extend perpendicular to the stacking direction D1, and are parallel to each other. The circuit layer 10 includes a conductive circuit 13 and conductive pads 14. The conductive circuit 13 is distributed in the circuit layer 10, and can extend in the stacking direction D1 and extend perpendicular to the stacking direction D1. The conductive circuit 13 includes separate wires 131, respectively connected to the chip 20, the passive components 30 and/or the conductive terminals 50. The some of the ends of the conductive circuit 13 are exposed from the upper surface 11 and the lower surface 12 of the circuit layer 10, and are connected to the conductive pads 14, the chip 20, and the passive components 30.

The formation of the circuit layer 10 may involve multiple deposition or coating processes, patterning processes, and planarization processes. The insulation layers, the conductive circuit 13 and the conductive pads 14 of the circuit layer 10 can be formed by deposition or coating processes. The deposition or coating processes may include a spin coating process, an electroplating process, an electroless process, a chemical vapor deposition (CVD) process, a physical vapor deposition (PVD) process, an atomic layer deposition (ALD) process, and other applicable processes and combinations thereof. The patterning process can be used to pattern the formed the insulation layers and the conductive circuit 13. The patterning process may comprise a photolithography process, an energy beam drilling process (for example, a laser beam drilling process, an ion beam drilling process, or an electron beam drilling process), an etching process, a mechanical drilling process, or other applicable processes and combinations. The planarization process can be used to provide a flat top surface for the formed the insulation layers and the conductive circuit 13 to facilitate subsequent processes. The planarization process may comprise a mechanical polishing process, a chemical mechanical polishing (CMP) process, or other applicable process and combinations thereof.

The circuit layer 10 can also be formed by an additive buildup process. The additive buildup process may comprise the alternating stacking of one or more dielectric layers and conductive patterns or traces of the circuit layer 10. The conductive patterns or traces fan out across the occupied space of the electronic device, or are in a fan-shaped layout allowing the electrical traces into the occupied space of the electronic device. The conductive patterns can be formed by a plating process such as an electroplating process or an electroless plating process. The conductive pattern may comprise a conductive material, such as copper or other metals. The dielectric layer of the circuit layer 10 can be made of a photo-definable organic dielectric such as polyimide (PI), benzocyclobutene (BCB), or polybenzoxazole (PBO). In other embodiments, the dielectric material of the redistribution layer 12 may also be an inorganic dielectric layer. The inorganic dielectric layer may comprise silicon nitride (Si3N4), silicon oxide (SiO2), or SiON. The inorganic dielectric layer can be formed by growing an inorganic dielectric layer using an oxidation or nitridation process.

The chip 20 can be a semiconductor chip. The chip 20 is disposed on the circuit layer 10, and connected to some of the ends of the conductive circuit 13. The chip 20 includes an upper surface 21, a lower surface 22, a side surface 23, and heat-dissipation grooves 224. The upper surface 21 and the lower surface 22 extend perpendicular to the stacking direction D1, and are parallel to each other. The side surface 23 is perpendicular to the upper surface 21 or the lower surface 22. The upper surface 21 is exposed from the encapsulation layer 40. The lower surface is connected to some of the ends of the upper surface 11 and/or the conductive circuit 13 of the circuit layer 10. The heat-dissipation grooves 224 of the chip 20 are formed on the upper surface 21. In the embodiment, the encapsulation layer 40 does not cover the heat-dissipation grooves 224 of the chip 20, and the encapsulation layer 40 is separated from the heat-dissipation grooves 224.

The passive components 30 may be resistors, capacitors, and/or inductors, but not limited thereto. The passive components 30 are disposed on the circuit layer 10, and connected to some of the ends of the conductive circuit 13. The encapsulation layer 40 covers the upper surface and the side surface of the passive components 30. The passive components 30 are connected to the upper surface 11 of the circuit layer 10 and/or some of the ends of the conductive circuit 13. In the embodiment, in the stacking direction D1, the height of the chip 20 relative to the circuit layer 10 is higher than the height of the passive components 30 relative to the circuit layer 10.

The encapsulation layer 40 covers the upper surface 11 of the circuit layer 10. Moreover, the encapsulation layer 40 may the side surface 23 of the cover chip 20, and the upper surface and the side surface of the passive components 30. The encapsulation layer 40 may be an electromagnetic interference (EMI) shielding layer, configured to provide electromagnetic protection for chip 20 and passive components 30. The upper surface 21 of the chip 20 is exposed from the upper surface 41 of the encapsulation layer 40. In the embodiment, the upper surface 21 of the chip 20 is connected to the upper surface 41 of the encapsulation layer 40, and the upper surface 21 of the chip 20 and the upper surface 41 of the encapsulation layer 40 forms a flat surface. In another embodiment, in the stacking direction D1, the upper surface 21 of the chip 20 is higher than the upper surface 41 of the encapsulation layer 40. In another embodiment, in the stacking direction D1, the upper surface 21 of the chip 20 is lower than the upper surface 41 of the encapsulation layer 40.

In one embodiment, the materials of the encapsulation layer 40 include insulation materials and conductive materials. The insulation materials may include epoxy resin, cyanate resin, bismaleimide triazine, glass fiber, polybenzoxazole, polyimide, nitride (for example, silicon nitride), oxide (for example, silicon oxide), silicon oxynitride, or similar insulating materials, insulating organic material mixed with epoxy resin and glass fiber, or ceramic material. The conductive materials are distributed in the insulation materials, and may include materials such as metal sheets, metal powders, metal fibers or metalized fibers.

The heat-dissipation grooves 224 of the chip 20 are formed on the upper surface 21 of the chip 20. In the embodiment, the heat-dissipation grooves 224 are separated from each other, and evenly distributed on the upper surface 21 of the chip 20. The heat-dissipation grooves 224 may linearly extend perpendicular to the stacking direction D1, and are parallel to each other. The thickness of the chip 20 is in a range from 5 times to 20 times the depth of the heat-dissipation grooves 224. In another embodiment, the thickness of the chip 20 is in a range from 6 times to 10 times the depth of the heat-dissipation grooves 224. The thickness of the chip 20 and the depth of the heat-dissipation grooves 224 are measured in the stacking direction D1. The total area of the heat-dissipation grooves 224 is greater than two-fifths of the upper surface 21 of the chip 20. The chip 20 includes at least 5 heat-dissipation grooves 224. In another embodiment, at least two of the heat-dissipation grooves 224 are connected to each other.

In the embodiment, since the heat-dissipation grooves 224 are formed on the chip 20, and the encapsulation layer 40 does not cover the heat-dissipation grooves 224 of the chip 20, the heat generated by the chip 20 can be dissipated quickly through the upper surface of the chip 20 and the heat-dissipation grooves 224. In other words, since the heat dissipation area of the chip 20 is increased by the heat-dissipation grooves 224, the heat dissipation efficiency of the semiconductor package device 1 is increased.

In the embodiment, the chip 20 may be optoelectronic devices, micro-electromechanical systems (MEMS), power amplifier chips, power management chips, biological identification devices, microfluidic systems, or a physical sensor that measures changes in heat, light levels, and pressure. Moreover, the chip 20 may be semiconductor chips, such as imaging sensor devices, light-emitting diodes (LEDs), solar cells, accelerators, gyroscopes, fingerprint readers, micro actuators, surface acoustic wave devices, or process sensors or ink printer heads, made by a wafer scale package (WSP) process.

As shown in FIG. 1, conductive terminals 50 are disposed under the lower surface 12 of the circuit layer 10, and connected to conductive pads 14. In the embodiment, the conductive terminals 50 may be solder balls. In another embodiment, conductive terminals 50 may be pins, but not limited thereto. For example, the conductive terminals 50 may be conductive balls, conductive pillars, conductive bumps, combinations thereof, or other forms and shapes formed by a ball-mounting process, an electroless plating process, or other suitable processes. According to the embodiments of the disclosure, a soldering process and a reflowing process can be performed to enhance adhesion between the conductive terminals 50 and the conductive pads 14.

In another embodiment, the semiconductor package device 1 may not include the conductive terminals 50.

In the embodiment, the thickness of the circuit layer 10 may be in a range from one-fifth to three times the thickness of the chip 20. The heat generated by the chip 20 is quickly transmitted to the conductive pad 14 or the conductive terminal 50 via the circuit layer 10, thereby enabling the semiconductor package device 1 to have good heat dissipation efficiency.

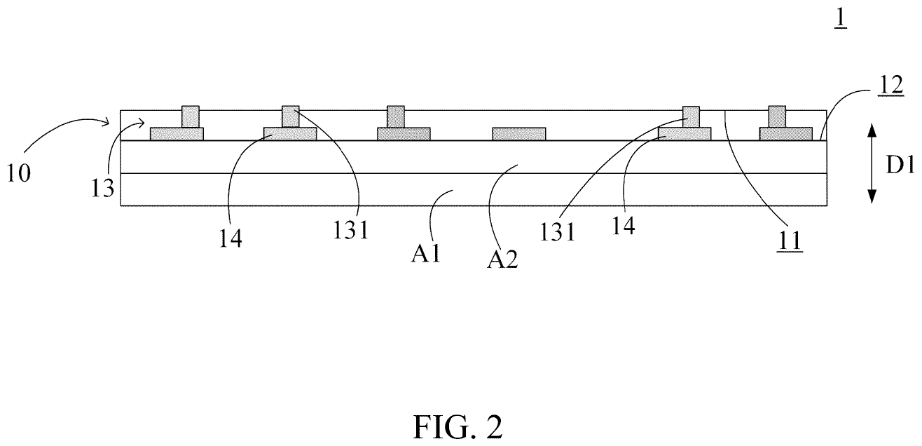

FIG. 2 to FIG. 5 are schematic diagrams of the semiconductor package device 1 in the manufacturing process according to an embodiment of the present disclosure. As shown in FIG. 2, the release layer A2 is formed on the substrate A1. The substrate A1 can be a wafer, a glass substrate or a silicon substrate. After that, the circuit layer 10 is formed on the release layer A2.

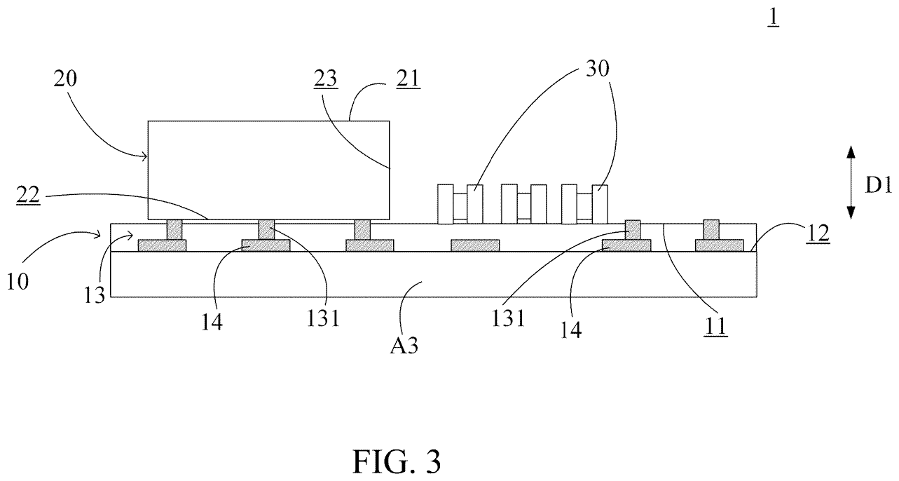

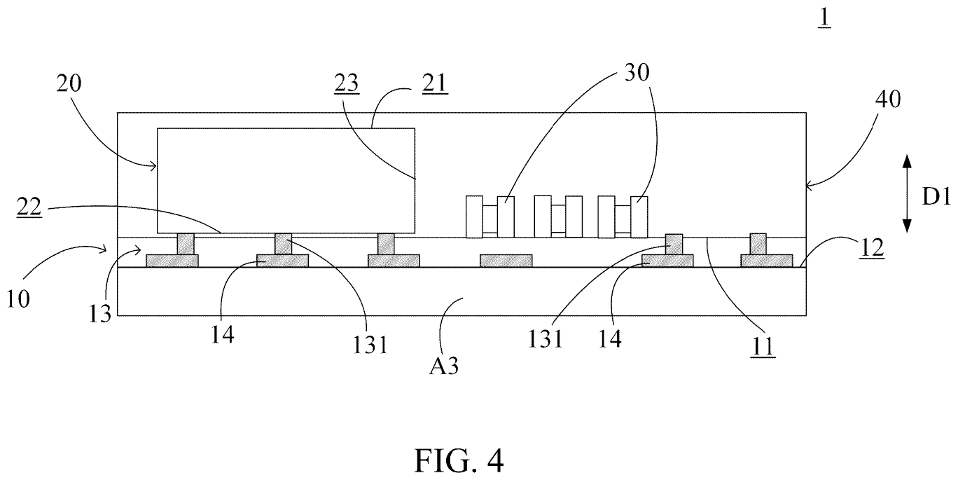

As shown in FIG. 3, the circuit layer 10 is peeled from the release layer A2 in FIG. 2, and attach the circuit layer 10 to another substrate A3. Next, the chip 20 and the passive components 30 are disposed on the circuit layer 10, and the chip 20 and the passive components 30 are connected to the conductive circuit 13. As shown in FIG. 4, the encapsulation layer 40 is formed on the circuit layer 10, the chip 20 and the passive components 30. The encapsulation layer 40 covers the upper surface 21 and the side surface 23 of the chip 20, and covers the upper surface and the side surface of the passive components 30.

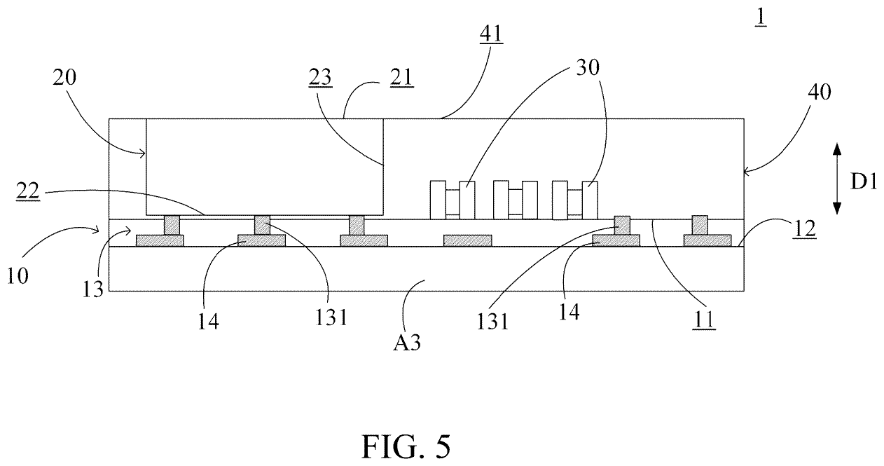

As shown in FIG. 5, the top of the encapsulation layer 40 is polished so that the upper surface 21 of the chip 20 is exposed from encapsulation layer 40. Next, the heat-dissipation grooves 224 are formed on the upper surface 21 of the chip 20. In the embodiment, the heat-dissipation grooves 224 are formed on the upper surface 21 of the chip 20 by laser. Afterward, as shown in FIG. 1, the substrate A3 of FIG. 5 is removed. The conductive terminals 50 are disposed under the circuit layer 10, and connected to the conductive pads 14.

In another embodiment, the top of the encapsulation layer 40 is not polished. The encapsulation layer 40 on the heat-dissipation grooves 224 can be removed, and the heat-dissipation grooves 224 are formed on the upper surface 21 of the chip 20 by laser.

According to the semiconductor package device 1 in the embodiment of the present disclosure, the heat-dissipation grooves 224 of the chip 20 are not covered by the encapsulation layer 40, and the heat-dissipation grooves 224 are formed on the chip 20 to increase the heat dissipation area of the chip 20. Therefore, the heat generated by the chip 20 can be dissipated quickly through the upper surface of the chip 20 and the heat-dissipation grooves 224, thereby increasing the heat dissipation efficiency of the semiconductor package device 1.

Many details are often found in the relevant art, thus many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will, therefore, be appreciated that the embodiments described above may be modified within the scope of the claims.

What is claimed is:

1. A semiconductor package device, comprising:
a circuit layer comprises a conductive circuit, and a plurality of conductive pads connected to the conductive circuit;
a chip disposed on the circuit layer, and connected to the conductive circuit, the chip has a side surface, an upper surface, and a plurality of heat-dissipation grooves formed on the upper surface of the chip; and
an encapsulation layer covering on the circuit layer, and the encapsulation layer covering on the side surface of the chip,
wherein the heat-dissipation grooves are exposed from the encapsulation layer.

2. The semiconductor package device as claimed in claim 1, wherein the heat-dissipation grooves are separated from each other and evenly distributed on the upper surface of the chip.

3. The semiconductor package device as claimed in claim 2, wherein the heat-dissipation grooves extend linearly and are parallel to each other.

4. The semiconductor package device as claimed in claim 1, wherein a thickness of the chip is in a range from 5 times to 20 times a depth of the heat-dissipation grooves.

5. The semiconductor package device as claimed in claim 1, further comprising a passive component disposed on the circuit layer, and connected to the conductive circuit, wherein the encapsulation layer covers an upper surface and a side surface of the passive component.

6. The semiconductor package device as claimed in claim 1, wherein the upper surface of the chip is connected to an upper surface of the encapsulation layer, and the upper surface of the chip and the upper surface of the encapsulation layer are formed as a flat surface.

7. A method of manufacturing a semiconductor package device, comprising:
(a) forming a circuit layer, the circuit layer is provided with a conductive circuit and a plurality of conductive pads connected to the conductive circuit;
(b) disposing a chip on the circuit layer, the chip is connected to the conductive circuit;
(c) forming an encapsulation layer on the circuit layer and on the chip, the encapsulation layer covers a side surface of the chip; and
(d) forming a plurality of heat-dissipation grooves on an upper surface of the chip.

8. The method of manufacturing the semiconductor package device as claimed in claim 7, wherein the step (b) further comprises:
disposing a passive component on the circuit layer, and the passive component is connected to the conductive circuit, and
the step (c) further comprises:
forming the encapsulation layer on the passive component, and the encapsulation layer covers an upper surface and a side surface of the passive component.

9. The method of manufacturing the semiconductor package device as claimed in claim 7, wherein the step (c) further comprises: the encapsulation layer covering the upper surface of the chip.

10. The method of manufacturing the semiconductor package device as claimed in claim 9, further comprising a step (c1) after the step (c): grinding a top portion of the encapsulation layer so that the upper surface of the chip is exposed from the encapsulation layer; and
polishing the top portion of the encapsulation layer.
